(19) United States
(12) Patent Application Publication
(10) Pub. No.: US 2025/0280710 A1
(43) Pub. Date: Sep. 4, 2025

(54) DISPLAY APPARATUS

(71) Applicant: LG Display Co., Ltd., Seoul (KR)

(72) Inventor: HyunSeok HONG, Gumi-si (KR)

(21) Appl. No.: 18/771,696

(22) Filed: Jul. 12, 2024

(30) Foreign Application Priority Data
Feb. 29, 2024 (KR) 10-2024-0029546

(51) Int. Cl. H10K 59/80

(52) U.S. Cl. CPC H10K 59/8731

(57) ABSTRACT

A display apparatus includes a substrate including a display area in which a plurality of pixels is disposed, and a first non-display area positioned outside the display area and surrounding the display area. The display apparatus further includes a low-potential voltage line disposed in the first non-display area. The display apparatus further includes a metallic pattern layer disposed on the low-potential voltage line.

### CROSS-REFERENCE TO RELATED APPLICATIONS

This application claims the priority of Korean Patent Application No. 10-2024-0029546 filed on Feb. 29, 2024, in the Korean Intellectual Property Office, the disclosure of which is incorporated herein by reference.

### BACKGROUND

### Technical Field

The present disclosure relates to a display apparatus.

### Description of the Related Art

As an information age enters, the field of display apparatus for visually displaying electrical information signals is rapidly developing, and researches for developing performances such as thinning, weight reduction, and low power consumption for various display apparatuses continue.

Exemplary display apparatuses include a liquid crystal display (LCD), an electro-wetting display (EWD), an organic light-emitting display (OLED), and the like.

Since a field emission display among them as a self-luminous display apparatus does not require a separate light source unlike the liquid crystal display, the field emission display may be manufactured lightly and thinly. Further, the field emission display is not only advantageous in terms of power consumption by low voltage driving, but also excellent even in color implementation, a response speed, a viewing angle, and a contrast ratio (CR), so the field emission display is expected to be utilized in various fields.

### BRIEF SUMMARY

Various embodiments of the present disclosure provide a display apparatus which may suppress a moisture penetration failure of a display panel.

Various embodiments of the present disclosure provide a display apparatus that suppresses the damage of the display panel which is caused by oxidation of lines due to moisture penetration of the display panel.

Technical benefits of the present disclosure are not limited to the above-mentioned benefits, and other benefits, which are not mentioned above, can be clearly understood by those skilled in the art from the following descriptions.

A display apparatus according to an exemplary embodiment of the present disclosure includes: a substrate including a display area in which a plurality of pixels is disposed, and a first non-display area positioned outside the display area and surrounding the display area; a low-potential voltage line disposed in the first non-display area; and a metallic pattern layer disposed on the low-potential voltage line.

Other detailed matters of the exemplary embodiments are included in the detailed description and the drawings.

In a display apparatus according to an exemplary embodiment of the present disclosure, a metallic pattern layer having a pattern for moisture penetration delay is formed on any one layer disposed in a non-display area of a display panel to suppress a moisture penetration failure which may occur around a link area.

In a display apparatus according to an exemplary embodiment of the present disclosure, panel damage may be suppressed which is caused by oxidization of lines, which may occur by moisture penetration which may occur around the link area of the display panel.

In a display apparatus according to an exemplary embodiment of the present disclosure, production energy may be reduced by suppressing the failure, and an ESG effect may be maximized through an effect such as high efficiency and long life-span.

The effects of the present disclosure are not limited to the aforementioned effects, and other effects, which are not mentioned above, will be apparently understood to a person having ordinary skill in the art from the following description.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram of a display apparatus according to an exemplary embodiment of the present disclosure;

FIG. 2 is a circuit diagram of a subpixel in the display apparatus according to an exemplary embodiment of the present disclosure;

FIG. 3 is a plan view of a display panel according to an exemplary embodiment of the present disclosure;

FIG. 4 is a plan view illustrating locations of power supply lines and a metallic pattern layer included in the display panel according to an exemplary embodiment of the present disclosure;

FIG. 5 is a cross-sectional view of a subpixel disposed in a display area of the display panel according to an exemplary embodiment of the present disclosure;

FIG. 6 is a cross-sectional view taken along line I-I′ of FIG. 4; and

FIG. 7 is a plan view of a part of the display panel according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification.

Further, in the following description of the present disclosure, a detailed explanation of known related technologies may be omitted to avoid unnecessarily obscuring the subject matter of the present disclosure.

The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly” is not used.

When an element or layer is referred to as being “on” another element or layer, it may be directly on the other element or layer, or intervening elements or layers may be present therebetween.

When a component is “linked,” “coupled,” or “connected” to another component, the component may be directly linked or connected to the other component. However, unless specifically stated otherwise, it should be understood that a third component may be interposed between the components which may be indirectly linked or connected.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

The features of various embodiments of the present disclosure can be partially or entirely coupled to or combined with each other and can be interlocked and operated in technically various ways, and respective embodiments can be carried out independently of or in association with each other.

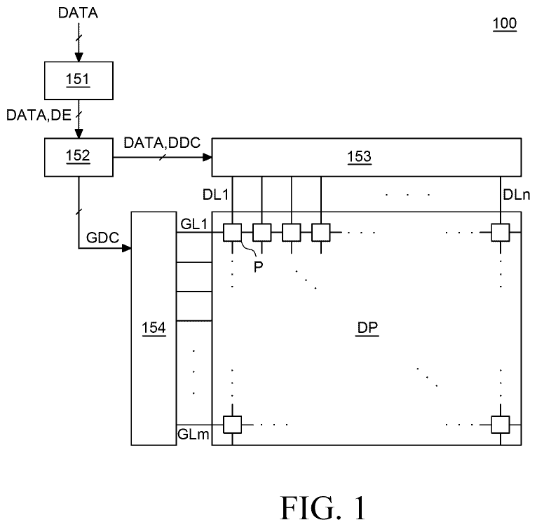

FIG. 1 is a block diagram of a display apparatus according to an exemplary embodiment of the present disclosure.

Referring to FIG. 1, the display apparatus 100 according to an exemplary embodiment of the present disclosure may include an image processor 151, a timing controller 152, a data driver 153, a gate driver 154, and a display panel DP.

The image processor 151 outputs a driving signal including a data signal DATA and a data enable signal DE supplied from the outside. The image processor 151 may output a driving signal including one or more of a vertical synchronization signal, a horizontal synchronization signal, and a clock signal in addition to the data enable signal DE.

The timing controller 152 receives the driving signal and the data signal DATA including the data enable signal DE from the image processor 151. The timing controller 152 outputs a gate timing control signal GDC for controlling an operation timing of the gate driver 154 based on the driving signal. The timing controller 152 outputs the data signal DATA supplied from the image processor 151, and a data timing control signal DDC for controlling an operation timing of the data driver 153.

In response to the data timing control signal DDC supplied from the timing controller 152, the data driver 153 samples and latches the data signal DATA supplied from the timing controller 152 and converts the sampled and latched data signal into gamma reference voltage and outputs the gamma reference voltage. Further, the data driver 153 outputs data signals through data lines DL1 to DLn.

The gate driver 154 may output a gate signal in response to the gate timing control signal GDC supplied from the timing controller 152, and at this time, the gate driver may shift a level of gate voltage, and output the gate signal. Further, the gate driver 154 outputs gate signals through gate lines GL1 to GLm.

The display panel DP includes a plurality of pixels P, and each of the plurality of pixels P emits light in response to the data signal and the gate signal supplied from the data driver 153 and the gate driver 154 to display an image.

One pixel P may be constituted by a plurality of subpixels. For example, one pixel P may include three or more subpixels that emit light of different colors. For example, in the display apparatus 100 according to an exemplary embodiment of the present disclosure, one pixel P may include subpixels that emit red, green, and blue. However, the number of subpixels included in one pixel P is not limited, and for example, may also further include a subpixel that emits white in addition to the subpixels that emit the red, the green, and the blue.

A plurality of gate lines GL1 to GLm extended in a first direction and a plurality of data lines DL1 to DLn extended in a second direction different from the first direction are disposed to cross on the display panel DP. Pixels P are defined at respective points where the plurality of gate lines and data lines are cross on the display panel DP.

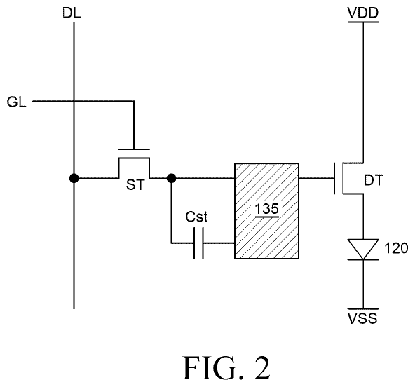

FIG. 2 is a circuit diagram of a subpixel in the display apparatus according to an exemplary embodiment of the present disclosure.

Referring to FIG. 2, the driving circuit of the subpixel according to an exemplary embodiment of the present disclosure may include a driving transistor DT, a switching transistor ST, a capacitor Cst, a gate line GL, a data line DL, and lines connected to power supplies VDD and VSS for pixel driving.

The light emitting device 120 may operate to emit light according to driving current formed by the driving transistor DT. The switching transistor ST may perform a switching operation so that the data signal supplied through the data line DL is stored in the capacitor Cst as data voltage in response to the gate signal supplied through the gate line GL. The driving transistor DT may operate so that constant driving current flows between a high-potential power supply line VDDL and a low-potential power supply line VSSL in response to the data voltage stored in the capacitor Cst.

Further, the subpixel may further include a compensation circuit 135.

The compensation circuit 135 may be a circuit for compensating threshold voltage of the driving transistor DT and the compensation circuit 135 may include one or more thin film transistors and capacitors. In this case, configurations and structures of a compensation thin film transistor and a compensation capacitor are not limited, and may be diversified according to a compensation type. For example, when the compensation circuit 135 is added to the subpixel, there may be various structures including 3T1C, 4T2C, 5T2C, 6T1C, 6T2C, 7T1C, 7T2C, etc.

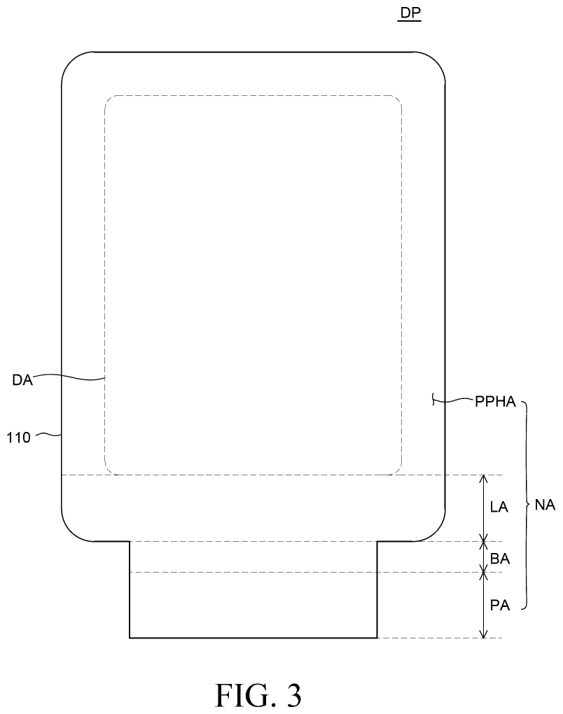

FIG. 3 is a plan view of a display panel according to an exemplary embodiment of the present disclosure.

Referring to FIG. 3, the display panel DP includes a substrate 110.

The substrate 110 is configured to support various components included in the display apparatus 100. The substrate 110 may be made of an insulation material. Further, the substrate 110 may be made of a transparent material. Further, the substrate 110 may be a rigid substrate, or a flexible substrate which is bendable, foldable, or rollable. In addition, the substrate 110 may be made of glass or a plastic material having flexibility. For example, when the substrate 110 is made of polyimide (PI) which is the plastic material, a manufacturing process of the display apparatus 100 is performed in a state that a support substrate made of glass is disposed below the substrate 110. After the manufacturing process of the display apparatus 100 is completed, the support substrate may be released.

As illustrated in FIG. 3, the substrate 110 of the display panel DP may be defined as a display area DA, and a non-display area NA which is positioned outside the display area DA, and in which a plurality of pixels P are not disposed.

The non-display area NA of the substrate 110 may be defined as a peripheral area PPHA disposed to surround the display area DA, a bending area BA extended from one side of the peripheral area PPHA and bent toward a back surface of the display panel DP, and a pad area PA extended from the bending area BA. Further, one side of the peripheral area PPHA of the substrate 110 may be defined as a link area LA, and the link area LA is positioned between the display area DA and the bending area BA.

Since the non-display area NA is not an area in which the image is displayed, the non-display area NA need not be viewed on a front of the display panel DP. Therefore, a partial area of the non-display area NA of the substrate 110 may be bent toward the back surface of the display panel DP, and for example, one edge of the substrate 110 may be bent toward the back surface of the display panel DP to have a predetermined curvature. In this case, the pad area PA may be positioned to overlap with the display area DA on the back surface of the display panel DP. Through this, the non-display area NA may be reduced while securing an area for the line and a driving circuit.

As illustrated in FIG. 3, the bending area BA is positioned between the display area DA and the pad area PA in the non-display area NA, which bends a part of the non-display area NA in one direction (e.g., in the direction of the back surface of the display panel DP). At this time, at least a part of the pad area PA may be disposed to overlap with the display area DA on the back surface of the display panel DP as the substrate 110 is bent in the bending area BA.

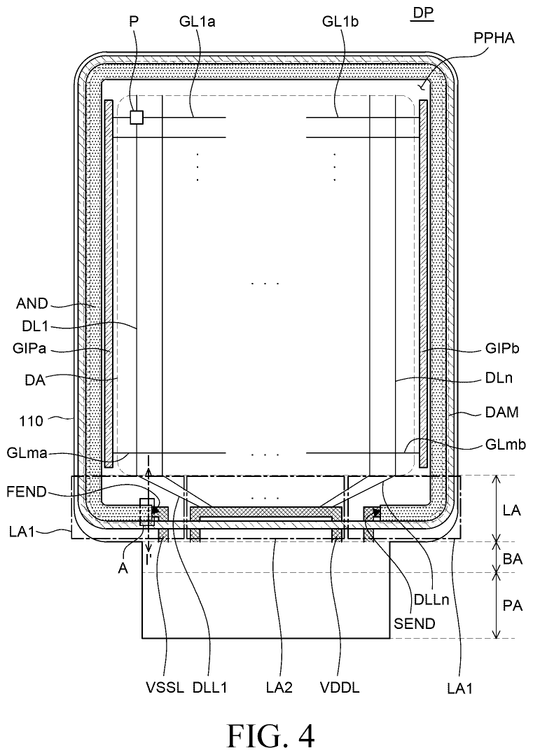

Hereinafter, a structure of the display apparatus 100 according to an exemplary embodiment of the present disclosure will be described in detail with reference to FIG. 4.

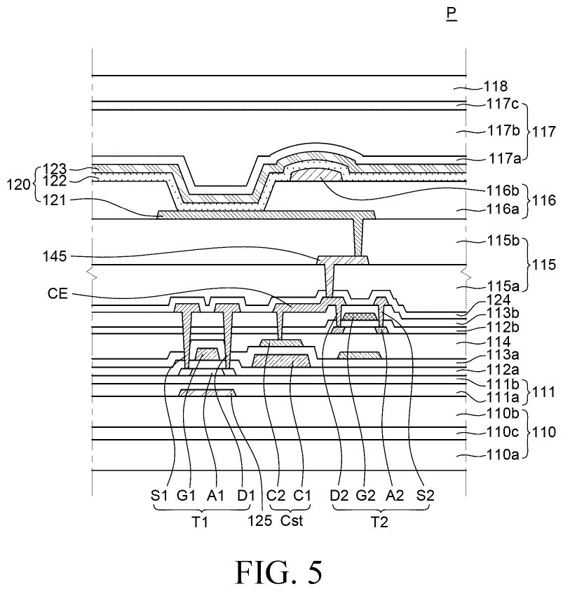

FIG. 4 is a plan view for explaining locations of power supply lines and a metallic pattern layer included in the display panel according to an exemplary embodiment of the present disclosure. FIG. 5 is a cross-sectional view of a pixel disposed in a display area of the display panel according to an exemplary embodiment of the present disclosure.

Referring to FIG. 4, the display area DA of the substrate 110 is an area where a plurality of pixels P implementing an image are disposed, and data lines DL1 to DLn extended in the first direction, and gate lines GL1a to GLma: GLa, GL1b to GLmb extended in the second direction may be disposed to cross each other in the display area DA, and pixels P may be disposed at every crossing areas in the form of a matrix.

One pixel P may include a plurality of subpixels each including a light emitting device and a pixel driving circuit for controlling a current amount which flows on the light emitting device. The pixel driving circuit may include a plurality of driving thin film transistors (TFTs).

In the peripheral area PPHA of the substrate 110, gate driving parts GIPa and GIPb of the gate driver, a low-potential voltage line VSSL, a metallic pattern layer AND, a first structure DAM (also referred to as a dam structure), a second structure 119a, and a third structure 119b are disposed.

In addition, in the peripheral area PPHA of the substrate 110, various lines for electrically connecting subpixels disposed in the display area DA to the gate driving parts GIPa and GIPb, the low-potential voltage line VSSL, and the high-potential voltage line VDDL, respectively may be disposed.

Further, various lines for electrically connecting a plurality of pads disposed in the pad area PA to the subpixels of the display area DA may be further disposed in the peripheral area PPHA of the substrate 110.

The non-display area NA of the substrate 110 as an area where the image is not displayed is an area where various lines, circuits, etc., for driving the subpixels disposed in the display area DA are disposed.

As illustrated in FIG. 4, the gate driving parts GIPa and GIPb may be disposed in the peripheral area PPHA of the substrate 110, and may be disposed at both sides of the display area DA, but are not limited thereto. The gate driving parts GIPa and GIPb provide a gate signal to the thin film transistor of the pixel driving circuit, and includes various gate driving circuits. In the display apparatus 100 according to an exemplary embodiment of the present disclosure, the gate driving parts GIPa and GIPb may be gate-in panels (GIPs) directly formed on the substrate 110.

By the display panel according to an exemplary embodiment of the present disclosure, the low-potential voltage line VSSL, the metallic pattern layer AND, the first structure DAM, the second structure 119a, and the third structure 119b are positioned to surround the display area DA in the peripheral area PPHA of the substrate 110.

The metallic pattern layer AND is disposed on the top of the low-potential voltage line VSSL along the low-potential voltage line VSSL, and an end (either a first end FEND or a second send SEND opposite the first end FEND) of the metallic pattern layer AND is positioned in the link area LA which is one side of the peripheral area PPHA. At this time, an end of the low-potential voltage line VSSL may be extended up to the pad area PA.

The high-potential voltage line VDDL is disposed in the link area LA which is one side of the peripheral area PPHA of the substrate 110. For example, referring to FIG. 4, each of both ends of the low-potential voltage line VSSL in the link area LA includes a first part extended along the display area DA, and a second part bent toward the pad area PA from an end of the first part, and then extended up to the pad area PA, and the high-potential voltage line VDDL may be disposed in an empty space LA2 at a center as second parts of both respective ends of the low-potential voltage line VSSL are spaced apart from each other.

Each subpixel disposed in the display area DA is electrically connected to the high-potential voltage line VDDL disposed in the non-display area NA through a high-potential power supply line to receive high-potential power VDD, and electrically connected to the low-potential voltage line VSSL through a low-potential power supply line to receive low-potential power VSS.

The low-potential power VSS supplied through the low-potential voltage line VSSL is transferred to the second electrode 123 through the metallic pattern layer AND. Referring to FIG. 4, the metallic pattern layer AND overlaps with the low-potential voltage line VSSL, and the end of the metallic pattern layer AND is spaced apart further from the high-potential voltage line VDDL than both ends of the low-potential voltage line VSSL in the link area LA. As a result, both ends (e.g., first end FEND and second end SEND) of the metallic pattern layer AND does not overlap with the high-potential voltage line VDDL from ap plan view (as shown in FIG. 4), and is electrically separated from the high-potential power VDD.

By the display panel according to an exemplary embodiment of the present disclosure, a pattern including a plurality of convexes and a plurality of concaves is formed on the end (e.g., first end FEND and second end SEND) of the metallic pattern layer AND to alleviate a moisture penetration failure into the display area DA, and suppress oxidation of a plurality of lines. The pattern of the metallic pattern layer AND will be described in detail in FIGS. 5 to 7 below. The plurality of patterns formed at the end (e.g., first end FEND and second end SEND) of the metallic pattern layer AND may also include a plurality of protrusions PTR and a plurality of recesses RCS.

In some embodiments, the metallic pattern layer AND continuously and contiguously extends from the first end FEND of the metallic pattern layer AND to the second end SEND of the metallic pattern layer AND (see FIG. 4).

As illustrated in FIG. 4, a plurality of structures DAM, 119a, and 119b may have a closed loop shape which entirely surrounds the display area DA. As shown, the plurality of structures DAM, 119a, and 119b is disposed along the peripheral portion (e.g., PPHA or adjacent to the edge of the display panel) of the display panel such that it surrounds the display area DA from a plan view. Further, the plurality of structures DAM, 119a, and 119b may be disposed not to overlap with the low-potential voltage line VSSL throughout the peripheral area PPHA except for the link area LA on a plane, and may be disposed to overlap parts of the low-potential voltage line VSSL and the high-potential voltage line VDDL at the link area LA, but is not limited thereto.

In some embodiments, the metallic pattern layer AND is disposed to overlap the low-potential voltage line VSSL from a plan view. In addition, the metallic pattern layer AND does not overlap with the high-potential voltage line VDDL from a plan view.

In FIG. 4, it is illustrated that one first structure DAM is disposed in the peripheral area PPHA of the substrate 110 for easy description, but in addition to the first structure DAM, one or more second and third structures 119a and 119b may be further positioned, and the numbers and heights thereof are not limited. For example, the plurality of structures DAM, 119a, and 119b may be disposed to surround the display area DA, and heights of at least two of the plurality of the first structure DAM, the second structure 119a, and the third structure 119b may be the same as or different from each other.

Referring to FIG. 4, a part of the low-potential voltage line VSSL, both ends of the metallic pattern layer AND, a part of the first structure DAM, parts of the second and third structures 119a and 119b, and the high-potential voltage line VDDL are disposed at one side (e.g., the link area LA) of the peripheral area PPHA adjacent to the bending area BA on the substrate 110.

The link area LA of the substrate 110 may include at least one first area in which the end of the low-potential voltage line VSSL is disposed, and a second area in which the high-potential voltage line VDDL is disposed. For example, based on a reference line passing through a center point of the display area DA and a center point of the bending area BA, in the link area LA, the low-potential voltage line VSSL may be positioned at both sides of the high-potential voltage line VDDL and disposed in an outer part of the substrate 110 than the high-potential voltage line VDDL. At this time, the second area in which the high-potential voltage line VDDL is disposed may be positioned between both first areas in which both ends of the low-potential voltage line VSSL are disposed.

The high-potential voltage line VDDL may be a bar shape having a predetermined length, in which the high-potential voltage line VDDL is disposed in parallel to a boundary line of the display area DA and a boundary line of the bending area BA, but is not limited thereto. The high-potential voltage line VDDL may be a form in which the high-potential voltage line VDDL itself may be bent on both ends toward the bending area BA, and extended up to the bending area BA, but is not limited thereto. For example, the signal line extended from the bending area BA may also be connected to a bar-shaped portion of the high-potential voltage line VDDL.

A portion in the high-potential voltage line VDDL, which is disposed in parallel to the boundary line with the display area DA and the boundary line with the bending area BA is disposed at an inner side of the first structure DAM on the plane. Further, the high-potential voltage line VDDL may be disposed to be extended up to the outer side of the first structure DAM, and to reach the bending area BA. At this time, the inner side of the first structure DAM in the link area LA may mean an inner side toward the display area DA. On the contrary, the outer side of the first structure DAM in the link area LA may mean an outer side toward an opposite side (e.g., the bending area BA) to the display area DA.

In the link area LA, the low-potential voltage line VSSL may be extended from a portion disposed in the peripheral area PPHA other than the link area LA, and disposed to be parallel to the boundary line with the display area DA and the boundary line with the bending area BA, but is not limited thereto. For example, a signal line extended from the bending area BA may also be connected to a portion of the low-potential voltage line VSSL vertically linked to be connected to the bending area BA.

A first portion in the low-potential voltage line VSSL, which is disposed in parallel to the boundary line with the display area DA and the boundary line with the bending area BA is disposed at an inner side of the first structure DAM on the plane. Further, the low-potential voltage line VSSL may include a second portion be disposed to be extended up to the outer side of the first structure DAM, and to reach the bending area BA.

The first structure DAM may be disposed in a form of surround the display area DA in the peripheral area PPHA, and disposed not to overlap with the portion disposed in parallel to the boundary line with the display area DA of each of the low-potential voltage line VSSL and the high-potential voltage line VDDL, and the boundary line with the bending area BA in the link area LA. That is, most of each of the low-potential voltage line VSSL and the high-potential voltage line VDDL in the link area LA may be disposed at the inner side of the first structure DAM. However, when each of the low-potential voltage line VSSL and the high-potential voltage line VDDL in the link area LA are bent toward the bending area BA, the first structure DAM may overlap with a part of the portion where each of the low-potential voltage line VSSL and the high-potential voltage line VDDL is bent.

Although not illustrated in FIG. 4, one or more second structures and third structures 119a and 119b may also be formed in a similar form to the first structure DAM. One or more second structures and third structures 119a and 119b may be disposed in a form of surrounding the display area DA in the peripheral area PPHA, e.g., a closed loop shape, and disposed between the display area DA and the first structure DAM on a plane. In some embodiments, the plurality of structures includes a closed loop shape that surrounds the display area DA from a plan view.

In the link area LA, the metallic pattern layer AND may be extended from a portion disposed in the peripheral area PPHA other than the link area LA, and disposed to be parallel to the boundary line with the display area DA and the boundary line with the bending area BA. Further, the metallic pattern layer AND may be extended along the low-potential voltage line VSSL on the top of the low-potential voltage line VSSL, and the end of the metallic pattern layer AND may be formed at a location adjacent to a portion where the low-potential voltage line VSSL is bent toward the bending area BA, but is not limited thereto.

Meanwhile, various link lines for transferring various signals or voltage to the lines disposed in the display area DA may be disposed at one area (e.g., the link area LA) of the peripheral area PPHA of the substrate 110. For example, a gate link line, a data link line, a high-potential voltage link line, a low-potential voltage link line, etc., may be disposed at the link area LA. As such, the respective link lines disposed at the link area LA may be extended and disposed to reach at least one of the bending area BA and the pad area PA.

For example, as illustrated in FIG. 4, a plurality of data link lines DLL1 to DLLn connected to the plurality of data lines DL1 to DLn disposed in the display area DA, respectively may be disposed at the link area LA. The plurality of data link lines DLL1 to DLLn may be extended up to the bending area BA and the pad area PA, and connected to a plurality of signal lines disposed in the pad area PA, respectively and electrically connected to a data pad connected to the signal line.

The pad area PA in the non-display area NA of the substrate 110 is an area where various lines and circuits for receiving external power, a data driving signal, etc., or transmitting/receiving a touch signal are disposed. A plurality of pads may be disposed in the pad area PA, and for example, a high-potential power supply pad, a data pad, a gate pad, and a low-potential voltage pad may be disposed.

Further, an external module, e.g., a driving integrated circuit (IC) such as a data driver IC or a gate driver IC may be positioned in the pad area PA. The driving IC disposed in the pad area PA may be connected to a plurality of signal lines, and connected to a plurality of data lines DL or a plurality of gate lines GL disposed in the display area DA through the plurality of signal lines. That is, the driving IC disposed in the pad area PA may be electrically connected to each of the plurality of pixels P.

In the present disclosure, it is assumed and described that the display apparatus 100 is an organic light emitting display apparatus, but the present disclosure is not limited thereto. For example, when the display apparatus 100 is the organic light emitting display apparatus, the subpixel may include a light emitting device 120 including an anode 121, a light emitting layer 122 on the anode 121, and a cathode 123 on the light emitting layer 122. At this time, the light emitting device 120 as the light emitting layer 122 may include an organic light emitting layer may further include a hole transport layer, a hole injection layer, an electron injection layer, and an electron transport layer in addition to the organic light emitting layer. Meanwhile, as another example, when the display apparatus 100 is a liquid crystal display device, the display apparatus 100 may also be configured to include a liquid crystal layer which is a display part.

Referring to FIG. 5, the structure of the pixel P disposed in the display area DA of the substrate 110 will be described in detail. In FIG. 5, a stacking structure of any one subpixel constituting the pixel P is illustrated as an example.

Referring to FIG. 5, the display apparatus 100 according to an exemplary embodiment of the present disclosure may include a substrate 110, a first buffer layer 111, a metallic layer 125, a first thin film transistor T1, a first gate insulation layer 112a, a first interlayer insulation layer 113a, a second buffer layer 114, a second thin film transistor T2, a second gate insulation layer 112b, a second interlayer insulation layer 113b, a connection electrode CE, a planarization layer 115, an auxiliary electrode 145, a bank part 116, a light emitting device 120, and an encapsulation part 117.

The substrate 110 serves to support and protect components of the display apparatus disposed thereabove.

For example, when the substrate 110 is made of polyimide (PI), moisture penetrates up to the thin film transistor or the light emitting device through the substrate 110 made of polyimide (PI), which may degrade the performance of the display apparatus 100. In order to suppress the degradation of the performance of the display apparatus 100 due to the moisture penetration, a double polyimide (PI) structure may be adopted as the substrate 110 in the display apparatus 100 according to an exemplary embodiment of the present disclosure.

For example, as illustrated in FIG. 5, the substrate 110 may include a first substrate 110a and a second substrate 110b each made of polyimide (PI), and an inorganic insulation layer 110c formed between the first substrate 110a and the second substrate 110b.

The inorganic insulation layer 110c may be configured by a single layer of silicon nitride (SiNx) or silicon oxide (SiOx), or a plurality of layers thereof. For example, a silicon dioxide (SiO2) material may be used, but the present disclosure is not limited thereto, and the inorganic insulation layer 110c may also be configured by double layers of silicon dioxide (SiO2) and silicon nitride (SiNx).

The inorganic insulation layer 110c blocks penetration of moisture into an upper portion of the second substrate 110b. Further, when an electric charge is charged into the first substrate 110a, the inorganic insulation layer 110c may block the charged electric charge from affecting the first thin film transistor T1 through the second substrate 110b. As described above, an electric charge charged in lower polyimide (PI) is blocked by the inorganic insulation layer 110c to improve the reliability of a product, and a layout process of a separate metallic layer for blocking the electric charge may be omitted, so the process may be simplified and production cost may be reduced.

The first buffer layer 111 is disposed on the substrate 110.

For example, as illustrated in FIG. 5, the first buffer layer 111 may include multi-buffer layers 111a and an active buffer layer 111b, and the multi-buffer layers 111a may be disposed on the substrate 110, and the active buffer layer 111b may be disposed on the multi-buffer layers 111a.

The metallic layer 125 may be disposed between the multi-buffer layers 111a and the active buffer layer 111b. That is, the metallic layer 125 is disposed on the multi-buffer layers 111a, and the active buffer layer 111b is disposed on the metallic layer 125. The metallic layer 125 may serve as a light shield, and may also be referred to as a light shielding layer.

The first thin film transistor T1 is disposed on the first buffer layer 111.

The first thin film transistor T1 includes a first active layer A1, a first gate electrode G1, a first source electrode S1, and a first drain electrode D1. However, the first source electrode S1 may become the first drain electrode, and the first drain electrode D1 may become the first source electrode.

The first active layer A1 is disposed on the first buffer layer 111. The first active layer A1 may include amorphous silicon or polycrystalline silicon. For example, the first active layer 121 may include low temperature poly silicon (LTPS). Since a poly silicon material is high in mobility (100 cm²/Vs or higher), low in energy consumption power, and excellent in reliability, the poly silicon material may be applied to a gate driver for a driving device and/or a multiplexer MUX for driving the thin film transistors for a display device. It is described that in the display apparatus 100 according to an exemplary embodiment of the present disclosure, the low temperature poly silicon (LTPS) is adopted the active layer A1 of the first thin film transistor T1, but the low temperature poly silicon (LTPS) may also be adopted as the active layer A2 of the second thin film transistor T2 according to characteristics of the display apparatus 100. Further, in the display apparatus 100 according to an exemplary embodiment of the present disclosure, the first active layer A1 adopting the low temperature poly silicon (LTPS) may be adopted as the active layer of the driving transistor, but the present disclosure is not limited thereto. For example, the first active layer A1 may also be adopted as the active layer of the switching transistor.

The first active layer A1 may include a first channel area in which a channel is formed when the first thin film transistor T1 is driven, and a first source area and a first drain area on both sides of the first channel area. The first source area of the first active layer A1 is connected to the first source electrode S1, and the first drain area is connected to the first drain electrode D1. For example, the source area and the first drain area may be configured by ion doping (impurity doping) of the first active layer A1. The first source area and the first drain area may be generated by ion-doping the poly silicon material and in this case, the first channel area may mean a portion which is not ion-doped but left as the poly silicon material.

The first gate insulation layer 112a is disposed on the first active layer A1.

The first gate insulation layer 112a may be disposed throughout the substrate 110 including the first active layer A1. For example, the first gate insulation layer 112a may be configured by a single layer of silicon nitride (SiNx) or silicon oxide (SiOx), or a plurality of layers thereof. Contact holes may be formed in the first gate insulation layer 112a in order to connect the first source electrode S1 and the first drain electrode D1 of the first thin film transistor T1 to the first source area and the first drain area of the first active layer A1 of the first thin film transistor T1, respectively.

The first gate electrode G1 of the first thin film transistor T1 and the first capacitor electrode C1 of the storage capacitor Cst are disposed on the first gate insulation layer 112a.

The first gate electrode G1 and the first capacitor electrode C1 may be configured by a single layer or a plurality of layers made of any one of molybdenum (MO), copper (Cu), titanium (Ti), aluminum (Al) chromium (Cr), gold (AU), nickel (Ni), and neodymium (Nd), or an alloy thereof.

The first gate electrode G1 may be formed on the first gate insulation layer 112a so as to overlap with the first channel area of the first active layer A1 of the first thin film transistor T1.

The first capacitor electrode C1 may also be omitted based on the driving characteristics of the display apparatus 100, and the structure and the type of thin film transistor. The first gate electrode G1 and the first capacitor electrode C1 may be made of the same material, and formed on the same layer. That is, the first gate electrode G1 and the first capacitor electrode C1 may be formed by the same process.

The first interlayer insulation layer 113a is disposed above the first gate insulation layer 112a, the first gate electrode G1, and the first capacitor electrode C1.

The first interlayer insulation layer 113a may be configured by a single layer of silicon nitride (SiNx) or silicon oxide (SiOx), or a plurality of layers thereof. In addition, contact holes for exposing the first source area and the first drain area of the first active layer A1 of the first thin film transistor T1 may be formed on the first interlayer insulation layer 113a.

The second capacitor electrode C2 of the storage capacitor Cst is disposed on the first interlayer insulation layer 113a.

The second capacitor electrode C2 may be configured by a single layer or a plurality of layers made of any one of molybdenum (MO), copper (Cu), titanium (Ti), aluminum (Al) chromium (Cr), gold (AU), nickel (Ni), and neodymium (Nd), or an alloy thereof. The second capacitor electrode C2 may be formed on the first interlayer insulation layer 113a to overlap with the first capacitor electrode C1. Further, the second capacitor electrode C2 may be made of the same material as the first capacitor electrode C1. The second capacitor electrode C2 may also be omitted based on the driving characteristics of the display apparatus 100, and the structure and the type of thin film transistor.

The second buffer layer 114 is disposed on the first interlayer insulation layer 113a and the second capacitor electrode C2.

The second buffer layer 114 may be configured by a single layer of silicon nitride (SiNx) or silicon oxide (SiOx), or a plurality of layers thereof. Contact holes for exposing the first source area and the first drain area of the first active layer A1 of the first thin film transistor T1 may be formed on the second buffer layer 114. Further, a contact hole for exposing the second capacitor electrode C2 of the storage capacitor Cst may be formed on the second buffer layer 114.

The second thin film transistor T2 is disposed on the second buffer layer 114.

The second thin film transistor T2 includes a second active layer A2, a second gate electrode G2, a second source electrode S2, and a second drain electrode D2. According to the design of the pixel circuit, the second source electrode S2 may become the second drain electrode, and the second drain electrode D2 may become the second source electrode.

The second active layer A2 is disposed on the second buffer layer 114. The second active layer A2 may be made of an oxide semiconductor. Since an oxide semiconductor material has a larger band gap than the silicon material, electrons cross the band gap in an off state, and as a result, off-current is low. Accordingly, a thin film transistor including the active layer made of the oxide semiconductor may be suitable for a switching transistor which an on time is short and an off time is maintained to be long, but the present disclosure is not limited thereto, and the thin film transistor may also be adopted as the driving transistor according to the characteristics of the display apparatus 100. In addition, since the off-current is low, the size of an auxiliary capacitor may be reduced, and as a result, the thin film transistor including the active layer made of the oxide semiconductor is suitable for a high-resolution display device. For example, the second active layer A2 is made of a metal oxide and may be made of various metal oxides such as indium-gallium-zinc-oxide (IGZO), etc. In an exemplary embodiment of the present disclosure, it is assumed and described that the second active layer A2 of the second thin film transistor T2 is made of IGZO among various metal oxides, but the present disclosure is not limited thereto, and the second active layer A2 may also be made of other metal oxides such as indium-zinc-oxide (IZO), indium-gallium-tin-oxide (IGTO), or indium-gallium-oxide (IGO) rather than IGZO. The second active layer A2 may be formed by depositing the metal oxide on the second buffer layer 114, performing a heat treatment process for stabilization, and then patterning the metal oxide.

The second active layer A2 may include a second channel area in which a channel is formed when the second thin film transistor T2 is driven, and a second source area and a second drain area on both sides of the second channel area. The second source area of the second active layer A2 is connected to the second source electrode S2, and the second drain area is connected to the second drain electrode D2.

In the display apparatus 100 according to an exemplary embodiment of the present disclosure, the light shielding layer serving the light shield may also be disposed below the second thin film transistor T2. For example, as illustrated in FIG. 5, a metallic layer performing the same function as the metallic layer 125 described above may be further disposed below the second buffer layer 114, and the metallic layer may be disposed to overlap with the second active layer A2 on the first interlayer insulation layer 113a.

The second gate insulation layer 112b is disposed on the second active layer A2.

The second gate insulation layer 112b may be disposed throughout the substrate 110 including the second active layer A2. For example, the second gate insulation layer 112b may be configured by a single layer of silicon nitride (SiNx) or silicon oxide (SiOx), or a plurality of layers thereof.

The second gate electrode G2 may be disposed on the second gate insulation layer 112b.

The second gate electrode 134 may be configured by a single layer or a plurality of layers made of any one of molybdenum (MO), copper (Cu), titanium (Ti), aluminum (Al) chromium (Cr), gold (AU), nickel (Ni), and neodymium (Nd), or an alloy thereof.

For example, a metallic material is formed on the second gate insulation layer 112b, a photoresist pattern is formed on the metallic material, and then the metallic material is wet-etched by using the photoresist pattern as a mask to form the second gate electrode G2. A wet etching liquid for etching the metallic material may adopt a material which selectively etches molybdenum (MO), copper (Cu), titanium (Ti), aluminum (Al) chromium (Cr), gold (AU), nickel (Ni), and neodymium (Nd), or an alloy thereof, which constitute a metallic material, and does not etch an insulation material.

The second interlayer insulation layer 113b may be disposed on the second gate insulation layer 112b and the second gate electrode G2.

Contact holes for exposing the first active layer A1 of the first thin film transistor T1 and the second active layer A2 of the second thin film transistor T2 may be formed on the second interlayer insulation layer 113b. For example, contact holes for exposing the first source area and the first drain area of the first active layer A1 in the first thin film transistor T1 may be formed on the second interlayer insulation layer 113b. Further, contact holes for exposing the second source area and the second drain area of the second active layer A2 in the second thin film transistor T2 may be formed on the second interlayer insulation layer 113b.

The second interlayer insulation layer 113b may be configured by a single layer of silicon nitride (SiNx) or silicon oxide (SiOx), or a plurality of layers thereof.

The connection electrode CE, the first source electrode S1 and the second drain electrode D1 of the first thin film transistor T1, and the second source electrode S2 and the second drain electrode D2 of the second thin film transistor T2 may be disposed above the second interlayer insulation layer 113b.

The connection electrode CE may be electrically connected to the second drain electrode D2 of the second thin film transistor T2. In addition, the connection electrode CE may be electrically connected to the second capacitor electrode C2 of the storage capacitor Cst through the contact holes formed on the second buffer layer 114 and the second interlayer insulation layer 113b. That is, the connection electrode CE may serve to electrically connect the second capacitor electrode C2 of the storage capacitor Cst and the second drain electrode D2 of the second thin film transistor T2.

Here, the first source electrode S1 and the first drain electrode D1 of the first thin film transistor T1 may be connected to the first active layer A1 of the first thin film transistor T1 through the contact holes formed on the first gate insulation layer 112a, the first interlayer insulation layer 113a, the second buffer layer 114, and the second interlayer insulation layer 113b, respectively.

Further, the second source electrode S2 and the second drain electrode D2 of the second thin film transistor T2 may be connected to the second active layer A2 through the contact hole formed on the second interlayer insulation layer 112b.

The connection electrode CE, the first source electrode S1 and the first drain electrode D1 of the first thin film transistor T1, and the second source electrode S2 and the second drain electrode D2 of the second thin film transistor T2 may be made of the same material by the same process.

For example, the connection electrode CE, the first source electrode S1 and the first drain electrode D1 of the first thin film transistor T1, and the second source electrode S2 and the second drain electrode D2 of the second thin film transistor T2 may be configured by a single layer or a plurality of layers made of any one of molybdenum (MO), copper (Cu), titanium (Ti), aluminum (Al) chromium (Cr), gold (AU), nickel (Ni), and neodymium (Nd), or an alloy thereof. For example, the connection electrode CE, the first source electrode S1 and the first drain electrode D1 of the first thin film transistor T1, and the second source electrode S2 and the second drain electrode D2 of the second thin film transistor T2 may be configured in a three-layer structure of titanium (Ti)/aluminum (Al)/titanium (Ti), and are not limited thereto.

The connection electrode CE may be integrally formed to be connected to the second drain electrode D2 of the second thin film transistor T2, but the present disclosure is not limited thereto.

The inorganic material layer 124 is disposed on the connection electrode CE, the first source electrode S1 and the first drain electrode D1 of the first thin film transistor T1, the second source electrode S2 and the second drain electrode D2 of the second thin film transistor T2, and the second interlayer insulation layer 113b.

The inorganic material layer 124 as a passivation layer for protecting the first thin film transistor T1 and the second thin film transistor T2 may be made of silicon oxide (SiOx), silicon nitride (SiNx), or a plurality of layers thereof.

A first planarization layer 115a of the planarization layer 115 is disposed on the inorganic material layer 124.

The first planarization layer 115a may be an organic layer for planarizing and protecting the upper portions of the first thin film transistor T1 and the second thin film transistor

T2. For example, the first planarization layer 115a may be made of an organic material such as acryl resin, epoxy resin, phenolic resin, polyamide resin, polyimide resin, etc.

The auxiliary electrode 145 is disposed on the first planarization layer 115a.

The auxiliary electrode 145 may be connected to the second drain electrode D2 of the second thin film transistor T2 through a contact hole of the first planarization layer 115a. The auxiliary electrode 145 may serve to electrically connect the second thin film transistor T2 and the first electrode 121. In addition, the auxiliary electrode 145 may be configured by a single layer or a plurality of layers made of any one of molybdenum (MO), copper (Cu), titanium (Ti), aluminum (Al) chromium (Cr), gold (AU), nickel (Ni), and neodymium (Nd), or an alloy thereof. The auxiliary electrode 145 may be made of the same material as the second source electrode S2 and the second drain electrode D2 of the second thin film transistor T2.

A second planarization layer 115b of the planarization layer 115 is disposed on the auxiliary electrode 145 and the first planarization layer 115a.

For example, the second planarization layer 115b may be made of an organic material such as acryl resin, epoxy resin, phenolic resin, polyamide resin, polyimide resin, etc.

The light emitting device 120 is disposed on the second planarization layer 115b. The light emitting device 120 includes the anode electrode 121, the light emitting layer 122, and the cathode electrode 123.

Further, a bank 116a of the bank part 116 is disposed on the second planarization layer 115b. The bank 116a may include an open area for exposing a portion corresponding to a light emitting area of each subpixel.

The anode electrode 121 of the light emitting device 120 is disposed on the second planarization layer 115b. The anode electrode 121 may be made of the metallic material, and may be electrically connected to the auxiliary electrode 145 through the contact hole provided on the second planarization layer 115b. For example, when the display apparatus 100 according to an exemplary embodiment of the present disclosure is a top emission type, the light emitted by the light emitting device 120 may be emitted to the upper portion of the substrate 110, and at this time, the anode electrode 121 may further a transparent conductive layer and a reflection layer on the transparent conductive layer. For example, the transparent conductive layer may be made of a transparent conductive oxide such as ITO, IZO, etc. Further, the reflection layer may be made of silver (Ag), aluminum (Al), gold (Au), molybdenum (Mo), tungsten (W), chromium (Cr) or an alloy thereof.

The bank 116a may be disposed while covering both ends of the anode electrode 121, and a part of the anode electrode 121 may be exposed through an open area of the bank 116a. For example, the bank 116a may be made of the inorganic insulation material such as silicon nitride (SiNx) or silicon oxide (SiOx), or the organic insulation material such as benzocyclobutene-based resin, acrylic-based resin, or imide-based resin, but is not limited thereto. A spacer 116b of the bank part 116 may be further disposed on the bank 116a.

The light emitting layer 122 of the light emitting device 120 is disposed at an open area of the bank 116a and on a periphery thereof. As a result, the light emitting layer 122 may be disposed on the anode electrode 121 exposed through the open area of the bank 116a. For example, the light emitting layer 122 may include a plurality of organic membranes. The cathode electrode 123 is disposed on the light emitting layer 122 of the light emitting device 120.

The encapsulation layer 117 is disposed on the light emitting device 120.

The encapsulation layer 117 may have a single-layer structure or a multi-layer structure. For example, as illustrated in FIG. 5, the encapsulation layer 117 may include a first encapsulation layer 117a, a second encapsulation layer 1178b, and a third encapsulation layer 117c. At this time, the first encapsulation layer 117a and the third encapsulation layer 117c may be configured by inorganic membranes, and the second encapsulation layer 117b may be configured by the organic membrane. Among the first encapsulation layer 117a, the second encapsulation layer 117b, and the third encapsulation layer 117c, the second encapsulation layer 117b may be the thickest and may serve as the planarization layer.

In the encapsulation layer 117, the first encapsulation layer 117a may be disposed most adjacent to the light emitting device 120. That is, the first encapsulation layer 117a may be disposed on the cathode electrode 123 of the light emitting device 120.

The first encapsulation layer 117a may be made of an inorganic insulation material which is enabled to be subject to low-temperature deposition. For example, the first encapsulation layer 117a may be made of silicon nitride (SiNx), silicon oxide (SiOx), silicon oxynitride (SiON), aluminum oxide (Al2O3), or the like. Since the first encapsulation layer 117a is deposited at a low-temperature atmosphere, the light emitting layer 122 containing the organic material which is vulnerable to a high-temperature atmosphere may be suppressed from being damaged upon a deposition process.

The second encapsulation layer 117b may be formed with a smaller area than the first encapsulation layer 117a. In this case, the second encapsulation layer 117b may be formed to expose both ends of the first encapsulation layer 117a. The second encapsulation layer 117b may play a buffering role of buffering stress between respective layers by bending of a flexible display apparatus, and play a role of strengthening planarization performance. For example, the second encapsulation layer 117b may be made of an organic insulation material such as acryl resin, epoxy resin, polyimide, polyethylene, or silicon oxycarbon (SiOC). For example, the second encapsulation layer 117b may also be formed through an inkjet scheme, but is not limited thereto.

The third encapsulation layer 117c may be formed on the top of the substrate 110 where the second encapsulation layer 117b is formed so as to cover a top surface and a side surface of each of the second encapsulation layer 117b and the first encapsulation layer 117a. At this time, the third encapsulation layer 117c may minimize or block penetration of external moisture or oxygen into the first encapsulation layer 117a and the second encapsulation layer 117b. For example, the third encapsulation layer 117c may be made of the inorganic insulation material such as silicon nitride (SiNx), silicon oxide (SiOx), silicon oxynitride (SiON), or aluminum oxide (Al2O3).

At least one blocking structure DAM blocking a flow of the second encapsulation layer 117b of the encapsulation layer 117 may be disposed in the non-display area NA.

Meanwhile, in the display apparatus 100 according to an exemplary embodiment of the present disclosure, a color filter and a touch sensor may be further disposed on the encapsulation part 117, but the present disclosure is not limited thereto.

For example, as illustrated in FIG. 5, a buffer membrane 118 which may be a touch buffer membrane for placing the touch sensor may be further disposed on the third encapsulation layer 117c.

The buffer membrane 118 may suppress the damage of the light emitting layer 122 of the light emitting device 120 which is vulnerable to a chemical liquid or moisture, or high temperature. For example, when the touch sensor is formed, a chemical liquid (development liquid or etching liquid) used for a process or moisture from the outside may be generated. In order to suppress the chemical liquid or moisture during manufacturing the touch sensor from penetrating the light emitting layer 122 containing the organic material, the buffer membrane 118 may be disposed, and the touch sensor may be disposed thereon. Further, the buffer membrane 118 may be enabled to be formed at a low temperature of a predetermined temperature (e.g., 100° C.) or less, and may be made of an organic insulation material having a low dielectric constant of 1 to 3. For example, the buffer membrane 118 may be made of an acryl-based, or epoxy-based, or siloxane-based material.

Further, the buffer membrane 118 may suppress the damage of the encapsulation part 117 and breakage of the touch electrode of the touch sensor due to the bending of the flexible display apparatus. For example, the buffer membrane 118 is made of the organic insulation material and has the planarization performance, and as a result, even though the flexible display apparatus is bent, the damage of the encapsulation part 117 and a breakage phenomenon of the touch electrode may be suppressed.

For example, the touch electrode of the touch sensor may be disposed on the buffer membrane 118. The touch electrode may include touch sensor metal and bridge metal positioned on different layers, and a touch interlayer insulation membrane may be disposed between the touch sensor metal and the bridge metal. For example, the touch sensor metal may include first touch sensor metal, second touch sensor metal, and third touch sensor metal disposed adjacent to each other. The first touch sensor metal and the second touch sensor metal may be electrically connected to each other, and when the third touch sensor metal is positioned between the first touch sensor metal and the second touch sensor metal, the first touch sensor metal and the second touch sensor metal may be electrically connected through the bridge metal on a different layer. The bridge metal may be insulated from the touch sensor metal by the touch interlayer insulation membrane.

Meanwhile, in the display apparatus 100 according to an exemplary embodiment of the present disclosure, an organic material layer covering the color filter and the touch sensor may be further disposed on the encapsulation part 117. For example, the organic material layer covering the touch electrode of the touch sensor may be disposed, and the organic material layer may be configured by an organic insulation membrane.

Further, in the display apparatus 100 according to an exemplary embodiment of the present disclosure, a polarization layer and a cover layer may also be further disposed on such an organic material layer on the encapsulation part 117.

The polarization layer may suppress reflection of external light on the display area DA. For example, when the display apparatus 100 is externally used, external natural light may be introduced and reflected by the reflection layer included in the anode electrode 121 of the light emitting device 120, or reflected by an electrode made of metal disposed below the light emitting device 120. An image of the display apparatus 100 may not be well viewed by the reflected light. The polarization layer may polarize the light introduced from the outside in a specific direction and suppress the reflected light from being emitted to the outside of the display apparatus 100 again.

Further, a cover glass may protect the components of the display apparatus 100 from external shock, and suppress damage such as scratch, etc. The cover glass may be bonded by an adhesive layer on the polarization layer. For example, the adhesive layer may be formed by using an optically transparent display adhesive such as pressure-sensitive adhesive, Optical Clear Adhesive (OCR), Optical Clear Resin (OCR), etc., but is not limited thereto.

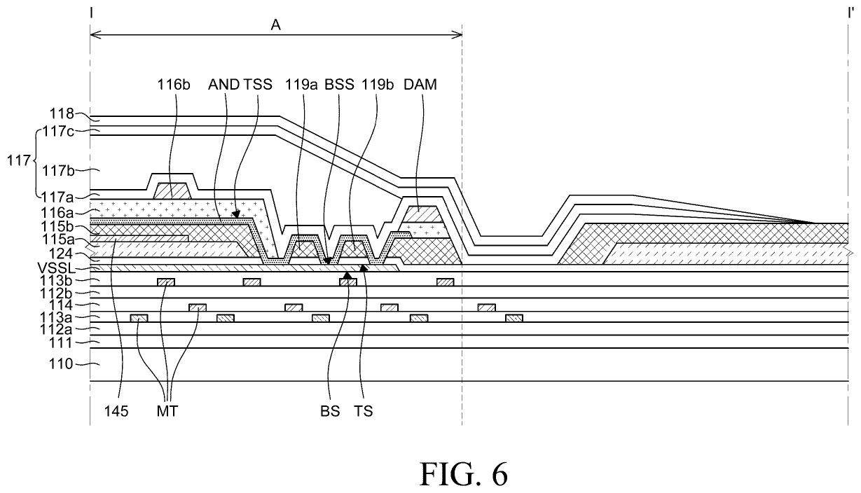

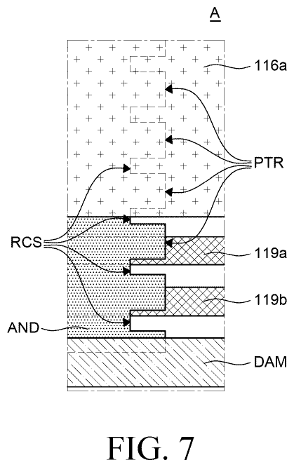

Hereinafter, referring to FIGS. 6 to 7, structures of the voltage line and the metallic pattern layer AND disposed in the non-display area NA of the substrate 110, and the pattern of the metallic pattern layer AND in the display apparatus 100 according to an exemplary embodiment of the present disclosure will be described in detail.

However, a component among the components disposed in the non-display area NA of the substrate 110 illustrated in FIGS. 6 to 7, which use the same reference numeral as the components described through FIGS. 3 to 5 above may mean substantially the same component. Therefore, for easy description, a duplicated description of the same or similar component as the component described through FIGS. 3 to 5 above among the components disposed in the non-display area NA of the substrate 110 illustrated FIGS. 6 to 7, and the resulting feature is omitted.

FIG. 6 is a cross-sectional view taken along line I-I′ of FIG. 4.

Referring to FIG. 6, a first buffer layer 111, a first gate insulation layer 112a, a first interlayer insulation layer 113a, a second buffer layer 114, a second gate insulation layer 112b, a second interlayer insulation layer 113b, an inorganic material layer 124, a first planarization layer 115a, a second planarization layer 115b, a bank 116a, a spacer 116b, a first encapsulation layer 117a, a second encapsulation layer 117b, a third encapsulation layer 117c, and a buffer layer 118 each extended from the display area DA may be sequentially disposed on the substrate 110 at one side (e.g., the link area LA) of the non-display area NA of the substrate 110.

A plurality of lines MT made of metal may be disposed on the first gate insulation layer 112a, the first interlayer insulation layer 113a, and the second gate insulation layer 112b. For example, various lines for electrically connecting subpixels disposed in the display area DA to the gate driving parts GIPa and GIPb, the low-potential voltage line VSSL, and the high-potential voltage line VDDL, respectively may be disposed on different layers. Further, various lines for electrically connecting a plurality of pads disposed in the pad area PA to the subpixels, the gate driving parts GIPa and GIPb, the low-potential voltage line VSSL, and the high-potential voltage line VDDL, respectively may be disposed on different layers. For example, at least some of the lines MT illustrated in FIG. 6 may be a plurality of data link lines DDL1 to DLLn connected to the plurality of data lines DL1 to DLn disposed in the display area DA, respectively, but are not limited thereto. At this time, the plurality of lines MT may be disposed on the same layer as at least one of the first gate electrode G1 of the first thin film transistor T1, the second capacitor electrode C2 of the storage capacitor Cst, and the second gate electrode G2 of the second thin film transistor T2, and made of the same material. The plurality of lines MT may be formed through the same process as at least one of the first gate electrode G1 of the first thin film transistor T1, the second capacitor electrode C2 of the storage capacitor Cst, and the second gate electrode G2 of the second thin film transistor T2.

The low-potential voltage line VSSL may be disposed on the second interlayer insulation layer 113b. For example, the low-potential voltage line VSSL may be disposed on the same layer as and made of the same material as at least one of the first source electrode S1 and the first drain electrode D1 of the first thin film transistor T1, and the second source electrode S2 and the second drain electrode D2 of the second thin film transistor T2 described in FIG. 5 above, but the present disclosure is not limited thereto. The low-potential voltage line VSSL may be formed through the same process as the first source electrode S1 and the first drain electrode D1 of the first thin film transistor T1, and the second source electrode S2 and the second drain electrode D2 of the second thin film transistor T2.

The inorganic material layer 124 is disposed to cover the low-potential voltage line VSSL.

The first structure DAM may be disposed on the inorganic material layer 124.

Further, the first planarization layer 115a and the second planarization layer 115b may be sequentially disposed on the inorganic material layer 124. The auxiliary electrode 145 may be disposed on the first planarization layer 115a. For example, each of the first planarization layer 115a and the second planarization layer 115b may be separated at an area where the auxiliary electrode 145 is not disposed therebetween. That is, the first structure DAM may be disposed between the first planarization layer 115a and the second planarization layer 115b separated and spaced apart from each other. Further, the second planarization layer 115b may be disposed to cover the first planarization layer 115a.

The display apparatus 100 according to an exemplary embodiment of the present disclosure may include at least one structure. For example, in FIG. 6, an example in which the display apparatus 100 includes the plurality of structures 119a, 119b, and DAM is illustrated, but only one structure DAM may be included.

A first structure DAM among the plurality of structures 119a, 119b, and DAM illustrated in FIG. 6 may be disposed farthest from the display area DA and disposed closest to the bending area BA. That is, the first structure DAM may be a blocking structure disposed at an outermost side in the peripheral area PPHA. Further, each of a second structure 119a and a third structure 119b among the plurality of structures 119a, 119b, and DAM may be disposed closer to the display area DA than the first structure DAM.

At this time, the second structure 119a and the third structure 119b may have a lower height than the first structure DAM, but are not limited thereto.

Further, the second structure 119a and the third structurer 119b may be made of the same material and disposed on the same layer as any one of the first planarization layer 115a and the second planarization layer 115b.

Meanwhile, the metallic pattern layer AND may be disposed on the second

planarization layer 115b. The metallic pattern layer AND may be linked to the first structure DAM, and disposed to pass through the tops of the second structure 119a and the third structure 119b. Further, a part of the inorganic material layer 124 may be removed before the metallic pattern layer AND is formed. Through this, the metallic pattern layer AND may be in contact with the low-potential voltage line VSSL. Further, the metallic pattern layer AND may be extended up to a part of the link area LA from the display area DA, disposed on the second planarization layer 115b in an area adjacent to the display area DA in the link area LA, and electrically connected to the second electrode 123 (e.g., a cathode) of the light emitting device 120 in the display area DA. For example, the metallic pattern layer AND may be disposed on the same layer and made of the same material as the first electrode 121 (e.g., an anode) of the light emitting device 120, but is not limited thereto. At this time, the metallic pattern layer AND is separated and electrically insulated from the first electrode 121 of the light emitting device 120.

The bank 116a and the spacer 116b of the bank part 116 may be disposed on the top of the first planarization layer 115a and the second planarization layer 115b. At this time, the bank part 116 may be disposed at an inner side than the plurality of structures 119a, 119b, and DAM. Further, the bank 116a may be disposed to cover the second planarization layer 115b.

The metallic pattern layer AND linked up to the first structure DAM may be disposed on the top of the second planarization layer 115b, and disposed on the bottom of the bank part 116. For example, an end of the metallic pattern layer AND may be formed on the bottom of the bank part 116, but the present disclosure is not limited thereto.

The encapsulation part 117 is disposed to cover the bank part 116 and the plurality of structures 119a, 119b, and DAM.

At this time, the first encapsulation layer 117a and the third encapsulation layer 117c may be disposed on the first structure DAM, and the flow of the second encapsulation layer 117b may be blocked by the first structure DAM.

For example, as illustrated in FIG. 6, the first encapsulation layer 117a and the third encapsulation layer 117c may be disposed on the plurality of structures 119a, 119b, and DAM, and extended along a side portion of the first structure DAM at the outermost side to cover the inorganic material layer 124. Further, a flow velocity of the second encapsulation layer 117b may be lowered by the second structure 119a and the third structure 119b, and the flow is blocked by the first structure DAM. That is, the flow of the second encapsulation layer 117b becomes low by at least one of the plurality of blocking structures 119a and 119b on an outer periphery of the non-display area NA, and a height from the substrate 110 is gradually decreased, and the flow may be blocked before the outermost blocking structure DAM or in contact with the outermost blocking structure DAM.

The first structure DAM may be formed in a predetermined height or more in order to block the flow of the second encapsulation layer 117b. To this end, the first structure DAM may be configured at least by one or more layers made of an organic material. For example, the first structure DAM may include a lower layer made of the same material as any one of the first planarization layer 115a and the second planarization layer 115b, an intermediate layer made of the same material as the bank 116a, and an upper layer made of the same material as the spacer 116b, but is not limited thereto.

Meanwhile, the low-potential power supply VSS transferred along the low-potential voltage line VSSL in the link area LA is transferred to the second electrode 123 through the metallic pattern layer AND, and an end of the metallic pattern layer AND does not overlap with the high-potential voltage line VDDL, and electrically separated from the high-potential power supply VDD.

Referring to FIG. 6, the metallic pattern layer AND has a first surface TSS (or a top surface TSS) and a second surface BSS (or a bottom surface BSS) opposite the first surface TSS. Similarly, the low-potential power voltage line VSSL has a first surface TS (or a top surface TS) and a second surface BS (or a bottom surface BS) opposite the first surface TS. In some embodiments, at least a portion of the second surface BSS of the metallic pattern layer AND directly contacts the first surface TS of the low-potential voltage line VSSL.

The plurality of structures includes a first structure 119a and a second structure 119b adjacent to the first structure 119a. In some embodiments, the first structure 119a and the second structure 119b are between the surface BSS of the metallic pattern layer AND and the surface TS of the low-potential voltage line VSSL.

The plurality of structures includes a dam structure DAM that is spaced apart from the surface TSS of the metallic pattern layer AND. In some embodiments, the dam structure DAM at least partially overlaps with the metallic pattern layer AND from a plan view.

In some embodiments, the encapsulation layer 117a, 117b, 117c is on the metallic pattern layer. In particular, a portion of the encapsulation layer 117a directly contacts the metallic pattern layer AND.

As illustrated in FIG. 7, in the display panel according to an exemplary embodiment of the present disclosure, the metallic pattern layer AND may be disposed in a direction perpendicular to the first structure DAM, the second structure 119a, and the third structure 119b.

As illustrated in FIG. 7, by the display panel according to an exemplary embodiment of the present disclosure, a pattern including a plurality of convexes PTR and a plurality of concaves RCS may be formed on one side of the metallic pattern layer AND.

More specifically, referring back to FIG. 4, when an area where the low-potential voltage line VSSL in the link area LA is defined as a first area and an area where the high-potential voltage line VDDL is disposed is defined as a second area, the metallic pattern layer AND may be disposed on the top of the low-potential voltage line VSSL. That is, the pattern of the metallic pattern layer AND may be positioned in the first area, and disposed on an edge toward the second area.

Referring back to FIG. 7, the pattern of the metallic pattern layer AND may include a plurality of convexes (or also referred to as protrusions PTR) and a plurality of concaves (or also referred to as recesses RCS), the plurality of convexes may overlap with a part of the second structure 119a or the third structure 119b, and the plurality of concaves may be positioned between the plurality of convexes. As a result, a moisture penetration delay path is formed in the metallic pattern layer AND to suppress moisture from penetrating the display area DA, and suppress a failure in which a plurality of lines are oxidized.

In FIG. 7, it is illustrated as an example that the metallic pattern layer AND is patterned in a quadrangular shape in which the plurality of convexes and the plurality of concaves included in the pattern of the metallic pattern layer AND are at right angles, but the shape of the pattern of the metallic pattern layer AND is not limited thereto. For example, the pattern of the metallic pattern layer AND may be patterned in various shapes such as a round form without a corner or a polygonal forming an acute angle.

As illustrated in FIG. 7, the plurality of recesses RCS of the metallic pattern layer AND overlaps with at least one of the first structure 119a, the second structure 119b, and the dam structure DAM from a plan view. In addition, the plurality of recesses RCS is positioned between the plurality of protrusions PTR to form a square-wave like shape.

The exemplary embodiments of the present disclosure can also be described as follows:

According to an aspect of the present disclosure, there is provided a display apparatus. The display apparatus includes a substrate including a display area in which a plurality of pixels are disposed, and a first non-display area positioned outside the display area and surrounding the display area. The display apparatus further includes a low-potential voltage line disposed in the first non-display area. The display apparatus further includes a metallic pattern layer disposed on the low-potential voltage line.

The display apparatus may further include at least one first structure disposed in the first non-display area and disposed to surround the display area.

The display apparatus may further include at least one of a second structure and a third structure disposed between the first structure and the display area on the first non-display area.

The second structure and the third structure may be disposed to surround the display area.

Each of the second structure and the third structure may be configured in a plurality of numbers.

The metallic pattern layer may include a pattern including a plurality of convexes and a plurality of concaves, the plurality of convexes overlap with a part of at least one of the second structure and the third structure, and the plurality of concaves is positioned between the plurality of convexes.

A part of the low-potential voltage line may overlap with at least one of the second structure and the third structure on the bottom of at least one of the second structure and the third structure.

The low-potential voltage line overlaps with at least a part of the metallic pattern layer.

A part of the metallic pattern layer may be disposed on the top of at least one of the second structure and the third structure, and the other part of the metallic pattern layer may be extended along a side portion of at least one of the second structure and the third structure and may be in contact with the low-potential voltage line.

The display apparatus may further include: a thin film transistor disposed in the display area, and including an active layer, a gate electrode, a source electrode, and a drain electrode; and a light emitting device including a first electrode, a light emitting layer, and a second electrode. The first electrode may be electrically connected to any one of the source electrode and the drain electrode. The first electrode may be electrically connected to the second electrode.

The active layer may be configured by any one of an oxide semiconductor layer or a low-temperature-poly-silicon (LTPS) semiconductor layer.

The display apparatus may further include an encapsulation layer extended up to a part of the non-display area from the display area, and disposed on the light emitting device. The metallic pattern layer overlaps with an end of the encapsulation layer.

The display apparatus may further include a first planarization layer disposed on the thin film transistor and a second planarization layer disposed on the first planarization layer. At least one of the second structure and the third structure is disposed on the same layer and made of the same material as the second planarization layer.

The metallic pattern layer may be extended up to a part of the first non-display area from the display area, disposed on the second planarization layer at one area adjacent to the display area in the first non-display area, and electrically connected to the second electrode of the light emitting device in the display area.

The substrate may further include a second non-display area outside the display area, and extended and bent from one area of the first non-display area.

The low-potential voltage line may have a shape in which both ends are separated from each other at one area of the first non-display area.

The display apparatus may further include a thin film transistor disposed in the display area, and including a gate electrode, a source electrode, and a drain electrode. The low-potential voltage line is made of the same material and disposed on the same layer as at least one of the source electrode and the drain electrode.

The display apparatus may further include a bank disposed on the top of the metallic pattern layer.

The display apparatus may further include a spacer disposed on the top of the bank.

The display apparatus may further include a high-potential voltage line disposed at one area of the first non-display area. The one area of the first non-display area includes one or more first areas in which the low-potential voltage line is disposed, and a second area in which the high-potential voltage line is disposed. The metallic pattern layer is disposed to overlap with the low-potential voltage line in the one or more first areas, and extended toward the second area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area in which a plurality of pixels is disposed, and a first non-display area positioned outside the display area;
a low-potential voltage line disposed in the first non-display area; and
a metallic pattern layer disposed on the low-potential voltage line.

2. The display apparatus of claim 1, further comprising:
at least one first structure disposed in the first non-display area and disposed to surround the display area.

3. The display apparatus of claim 2, further comprising:
at least one of a second structure and a third structure disposed between the first structure and the display area on the first non-display area.

4. The display apparatus of claim 3, wherein the second structure and the third structure are disposed to surround the display area.

5. The display apparatus of claim 3, wherein each of the second structure and the third structure is configured in a plurality of numbers.

6. The display apparatus of claim 3, wherein the metallic pattern layer includes a pattern including a plurality of convexes and a plurality of concaves,
wherein the plurality of convexes overlap with a part of at least one of the second structure and the third structure, and
wherein the plurality of concaves is positioned between the plurality of convexes.

7. The display apparatus of claim 3, wherein a part of the low-potential voltage line overlaps with at least one of the second structure and the third structure on the bottom of at least one of the second structure and the third structure.

8. The display apparatus of claim 3, wherein the low-potential voltage line overlaps with at least a part of the metallic pattern layer.

9. The display apparatus of claim 8, wherein a part of the metallic pattern layer is disposed on the top of at least one of the second structure and the third structure, and
wherein the other part of the metallic pattern layer is extended along a side portion of at least one of the second structure and the third structure and is in contact with the low-potential voltage line.

10. The display apparatus of claim 3, further comprising:
a thin film transistor disposed in the display area, and including an active layer, a gate electrode, a source electrode, and a drain electrode; and
a light emitting device including a first electrode, a light emitting layer, and a second electrode, wherein the first electrode is electrically connected to any one of the source electrode and the drain electrode,
wherein the first electrode is electrically connected to the second electrode.

11. The display apparatus of claim 10, wherein the active layer is configured by any one of an oxide semiconductor layer or a low-temperature-poly-silicon (LTPS) semiconductor layer.

12. The display apparatus of claim 10, further comprising:
an encapsulation layer extended up to a part of the non-display area from the display area, and disposed on the light emitting device,
wherein the metallic pattern layer overlaps with an end of the encapsulation layer.

13. The display apparatus of claim 10, further comprising:
a first planarization layer disposed on the thin film transistor and a second planarization layer disposed on the first planarization layer,
wherein at least one of the second structure and the third structure is disposed on the same layer and made of the same material as the second planarization layer.

14. The display apparatus of claim 13, wherein
the metallic pattern layer is extended up to a part of the first non-display area from the display area, disposed on the second planarization layer at one area adjacent to the display area in the first non-display area, and electrically connected to the second electrode of the light emitting device in the display area.

15. The display apparatus of claim 1, wherein the substrate further includes a second non-display area outside the display area, and extended and bent from one area of the first non-display area.

16. The display apparatus of claim 1, wherein the low-potential voltage line has a shape in which both ends are separated from each other at one area of the first non-display area.

17. The display apparatus of claim 1, further comprising:
a thin film transistor disposed in the display area, and including a gate electrode, a source electrode, and a drain electrode,
wherein the low-potential voltage line is made of the same material and disposed on the same layer as at least one of the source electrode and the drain electrode.

18. The display apparatus of claim 1, further comprising:
a bank disposed on the top of the metallic pattern layer.

19. The display apparatus of claim 18, further comprising:
a spacer disposed on the top of the bank.

20. The display apparatus of claim 1, further comprising:
a high-potential voltage line disposed at one area of the first non-display area,
wherein the one area of the first non-display area includes one or more first areas in which the low-potential voltage line is disposed, and a second area in which the high-potential voltage line is disposed, and
the metallic pattern layer is disposed to overlap with the low-potential voltage line in the one or more first areas, and extended toward the second area.

21. A display apparatus comprising:
a display panel having a display area and a peripheral area adjacent to the display area, the peripheral area being a non-display area;
a low-potential voltage line;
a high-potential voltage line;
a metallic pattern layer disposed to overlap the low-potential voltage line from a plan view,
wherein the metallic pattern layer does not overlap with the high-potential voltage line from a plan view,
wherein the metallic pattern layer includes a first end and a second end opposite the first end, and
wherein either the first end or the second end or both includes a plurality of protrusions and a plurality of recesses.

22. The display apparatus of claim 21, wherein the metallic pattern layer continuously and contiguously extends from the first end of the metallic pattern layer to the second end of the metallic pattern layer.

23. The display apparatus of claim 21, wherein the low-potential voltage line has a first surface and a second surface opposite the first surface,
wherein the metallic pattern layer has a first surface and a second surface opposite the first surface, and
wherein at least a portion of the first surface of the metallic pattern layer directly contacts the second surface of the low-potential voltage line.

24. The display apparatus of claim 23, comprising:
a plurality of structures including a first structure and a second structure adjacent to the first structure,
wherein the first structure and the second structure are between the first surface of the metallic pattern layer and the second surface of the low-potential voltage line.

25. The display apparatus of claim 24, wherein the plurality of structures includes a dam structure,
wherein the dam structure is spaced apart from the second surface of the metallic pattern layer, and
wherein the dam structure at least partially overlaps with the metallic pattern layer from a plan view.

26. The display apparatus of claim 24, wherein the plurality of structures includes a closed loop shape that surrounds the display area from a plan view.

27. The display apparatus of claim 20, comprising:
a plurality of structures including a first structure, a second structure, and a dam structure, the plurality of structures having a closed loop shape that surrounds the display area from a plan view,
wherein the plurality of recesses of the metallic pattern layer overlaps with at least one of the first structure, the second structure, and the dam structure from a plan view, and
wherein the plurality of recesses is positioned between the plurality of protrusions.

28. The display apparatus of claim 20, comprising:
an encapsulation layer on the metallic pattern layer,
wherein a portion of the encapsulation layer directly contacts the metallic pattern layer.
